(19) United States
(12) Patent Application Publication
(10) Pub. No.: US 2026/0185788 A1
(43) Pub. Date: Jul. 2, 2026

(54) WATER CIRCULATION MAT

(71) Applicant: KYUNGDONG NAVIEN CO., LTD., Pyeongtaek-si (KR)

(72) Inventors: Jae Hwi Yang, Seoul (KR); Tae Won Yun, Seoul (KR)

(21) Appl. No.: 19/436,419

(22) Filed: Dec. 30, 2025

(30) Foreign Application Priority Data
Dec. 31, 2024 (KR) 10-2024-0202257

(51) Int. Cl. F28F 27/02; F28D 15/02

(52) U.S. Cl. CPC F28F 27/02; F28D 15/0275; F28F 2250/08

(57) ABSTRACT

Provided is a water circulation mat. The water circulation mat includes a mat part including an internal passage, and a body part that is connected to the internal passage, the body part includes a case including an accommodation space in an interior thereof, a cooling part that is disposed at a lower portion of the accommodation space, a heat dissipation module, at least a portion of which is connected to the cooling part, and that is disposed on a front side of the cooling part in the accommodation space, a first fan that is disposed at an upper portion of the heat dissipation module in the accommodation space, and a second fan that is disposed perpendicularly to the first fan.

### CROSS-REFERENCE TO RELATED APPLICATION

This application claims the benefit of priority to Korean Patent Application No. 10-2024-0202257, filed in the Korean Intellectual Property Office on Dec. 31, 2024, the entire contents of which are incorporated herein by reference.

### TECHNICAL FIELD

The present disclosure relates to a water circulation mat.

### BACKGROUND

A water circulation mat refers to a mat that circulates water through passages provided in the mat to cause an appropriate temperature change. The water circulation mat may perform heating or cooling through the mat. The water circulation mat includes a hot water mat capable of heating, a cold water mat capable of cooling, and a four-season mat or a hot-and-cold water circulation mat capable of both heating and cooling. The water circulation mat may include a mat part that includes a passage through which water circulates, and a body part for supplying hot or cold water to the mat part.

The hot-and-cold water circulation mat may generate a large amount of heat in the body part because both a device for heating water and a device for cooling water are provided, and accordingly, efficient heat dissipation performance is required.

### SUMMARY

The present disclosure has been made to solve the above-mentioned problems occurring in the prior art while advantages achieved by the prior art are maintained intact.

An aspect of the present disclosure provides a water circulation mat that may improve heat dissipation efficiency by performing heat dissipation for a cooling part and a PBA module through a single heat dissipation part, and that may independently controlling temperatures on left and right sides.

The technical problems to be solved by the present disclosure are not limited to the aforementioned problems, and any other technical problems not mentioned herein will be clearly understood from the following description by those skilled in the art to which the present disclosure pertains.

According to an embodiment of the present disclosure, a water circulation mat includes a mat part including an internal passage that is configured such that water flows in an interior thereof, and a body part that is connected to the internal passage, and supplies water to the internal passage or receives water returned from the internal passage, the body part includes a case including an accommodation space in an interior thereof, a cooling part that is disposed at a lower portion of the accommodation space, a heat dissipation module, at least a portion of which is connected to the cooling part, and that is disposed on a front side of the cooling part in the accommodation space, a first fan that is disposed at an upper portion of the heat dissipation module in the accommodation space, and forms a flow of air passing through the heat dissipation module in an upward direction, and a second fan that is disposed perpendicularly to the first fan, and forms a flow of air such that air passing through the heat dissipation module is discharged in a forward direction of the case.

In an embodiment, a PBA module may be disposed in a space of the accommodation space located at an upper portion of the first fan, and the flow of air formed by the first fan may pass through the heat dissipation module to cool the cooling part, and then may flow to the space, in which the PBA module is disposed, to cool the PBA module.

In an embodiment, the heat dissipation module may include a heat pipe that is connected to the cooling part to be thermally transferable, and a plurality of heat dissipation fins, through which the heat pipe passes.

In an embodiment, the cooling part may include a Peltier element that cools water to be supplied to the internal passage.

In an embodiment, the water circulation mat may further include a tank part including a storage space, in which water is stored in an interior thereof, including a heater disposed in the interior of the storage space.

In an embodiment, the tank part may be disposed on a rear side of the space, in which the PBA module is disposed, and a partition wall including an insulating material may be disposed between the tank part and the PBA module.

In an embodiment, the internal passage may include a first internal passage and a second internal passage separated from each other, the body part may include a first return passage connected to the first internal passage and a second return passage connected to the second internal passage, and when an operation mode for supplying cooled water to the internal passage is defined as a cooling mode, and an operation mode for supplying heated water to the internal passage is defined as a heating mode, each of the first return passage and the second return passage may include two branch passages, and water flows through one branch passage in the cooling mode and water flows through the remaining branch passage in the heating mode.

In an embodiment, the first return passage may include a first branch return passage that is configured such that returned water flows to the cooling part, and a second branch return passage that is configured such that returned water flows to the tank part, and the second return passage may include a third branch return passage that is configured such that returned water flows to the cooling part, and a fourth branch return passage that is configured such that returned water flows to the tank part.

In an embodiment, the body part may further include a pump part that pumps water, and a first cooling valve that is provided at an inlet end of the pump part, and to which the first branch return passage and the second branch return passage are connected, and the first cooling valve may control a flow of water between the return passage and the pump part.

In an embodiment, the body part may further include a first heating valve that is connected to the tank part, and to which the second branch return passage and the fourth branch return passage are connected, and the first heating valve may control a flow of water between the return passage and the tank part.

In an embodiment, the body part may further include a water outlet passage that is connected to the internal passage, a second cooling valve that controls a flow of water cooled in the cooling part to the water outlet passage, and a second heating valve that controls a flow of water heated in the tank part to the water outlet passage.

In an embodiment, the body part may further include a first return valve that is provided at a branch point of the first return passage, and the first return valve may perform a control to block returned water from flowing to the first branch return passage and the second branch return passage, or to cause the returned water to flow to any one of the first branch return passage and the second branch return passage.

In an embodiment, the body part may further include a second return valve that is provided at a branch point of the second return passage, and the second return valve may perform a control to block returned water from flowing to the third branch return passage and the fourth branch return passage, or to cause the returned water to flow to any one of the third branch return passage and the fourth branch return passage.

In an embodiment, in the cooling mode, the first cooling valve and the second cooling valve may be opened, the first heating valve and the second heating valve may be closed, and the first return valve and the second return valve may cause returned water to flow to the first branch return passage and the third branch return passage, respectively.

In an embodiment, water introduced into the first branch return passage and the third branch return passage may be cooled to a specific temperature after sequentially passing through the first cooling valve, the pump part, the cooling part, the second cooling valve, and the water outlet passage, and then may be discharged to the first internal passage or the second internal passage.

In an embodiment, in the heating mode, the first heating valve and the second heating valve may be opened, the first cooling valve and the second cooling valve may be closed, and the first return valve and the second return valve may cause returned water to flow to the second branch return passage and the fourth branch return passage, respectively.

in an embodiment, water introduced into the second branch return passage and the fourth branch return passage may be heated to a specific temperature after sequentially passing through the first heating valve, the tank part, the pump part, the second heating valve, and the water outlet passage, and then may be discharged to the first internal passage or the second internal passage.

In an embodiment, the body part may further include a processor that controls an operation of the body part, a first return temperature sensor provided in the first return passage, and a second return temperature sensor provided in the second return passage, and the processor may control operations of the cooling mode and the heating mode based on temperature information measured by the first return temperature sensor and the second return temperature sensor.

### BRIEF DESCRIPTION OF THE DRAWINGS

The above and other objects, features and advantages of the present disclosure will be more apparent from the following detailed description taken in conjunction with the accompanying drawings:

FIG. 1 is a view illustrating a body part of a water circulation mat according to an embodiment of the present disclosure;

FIG. 2 is a view schematically illustrating a body part and a mat part of a water circulation mat according to an embodiment of the present disclosure;

FIG. 3 is a view illustrating a tank part and a pump part of a water circulation mat according to an embodiment of the present disclosure;

FIG. 4 is a view illustrating a tank part and a pump part of a water circulation mat according to an embodiment of the present disclosure;

FIG. 5 is a view illustrating an operation of a cooling mode in a water circulation mat according to an embodiment of the present disclosure; and

FIG. 6 is a view illustrating an operation of a heating mode in a water circulation mat according to an embodiment of the present disclosure.

### DETAILED DESCRIPTION

Hereinafter, some embodiments of the present disclosure will be described in detail with reference to the accompanying drawings. In adding reference numerals in the drawings, the same reference numerals will be used throughout to designate the same or equivalent components. In describing embodiments of the present disclosure, detailed descriptions associated with well-known functions or configurations will be omitted if they may make subject matters of the present disclosure unnecessarily obscure.

In the specification, a forward/rearward direction, a leftward/rightward direction, and an upward/downward direction are referred for convenience, and may be directions that are perpendicular to each other. However, the directions are determined relatively to a direction, in which components of a body part of a water circulation mat are arranged, and the upward/downward direction does not necessarily mean a vertical direction.

Additionally, terms including ordinal numbers, such as “first,” “second,” etc., used herein may be used to describe various components, but the components are not limited by the terms, and the terms are used only for the purpose of distinguishing one component from another. For example, without departing from the scope of the present disclosure, a first component may be referred to as a second component, and similarly, a second component may be referred to as a first component. The term “and/or” includes any combination of a plurality of related listed items or any one of the plurality of related listed items.

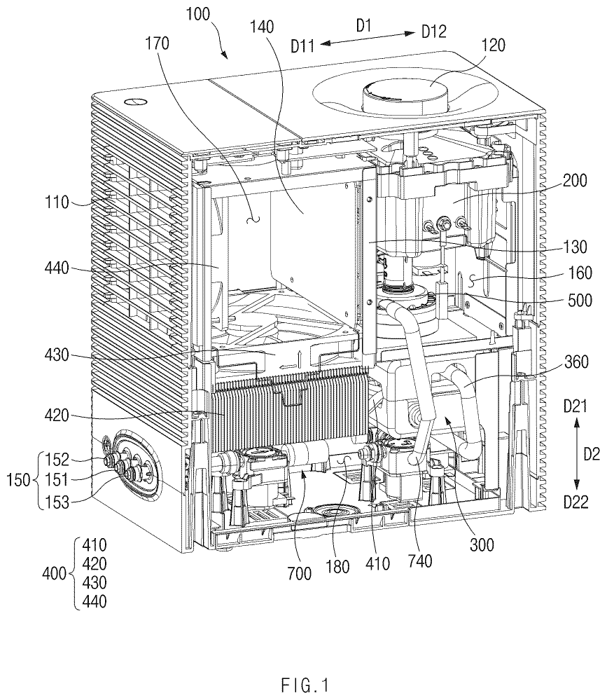

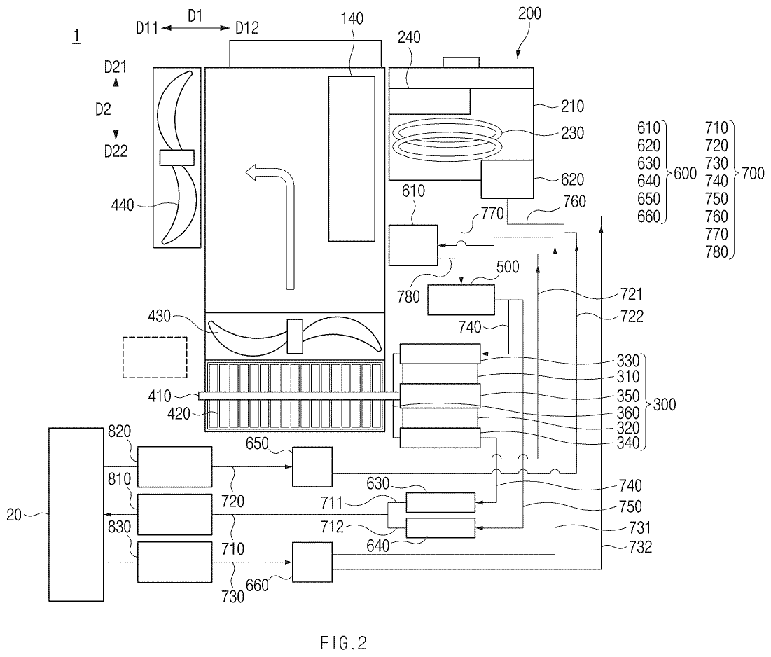

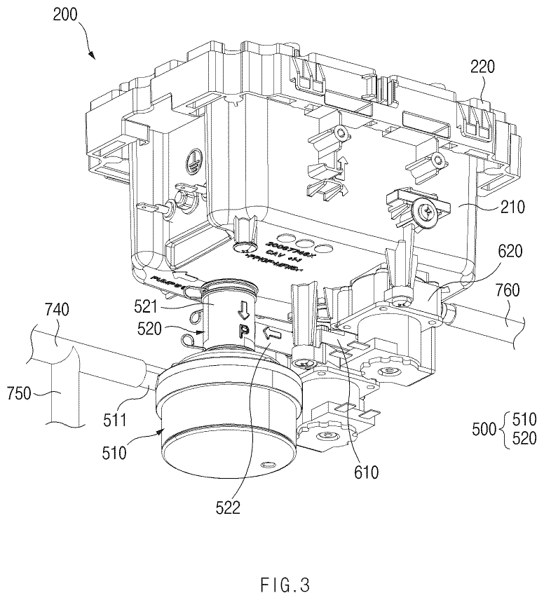

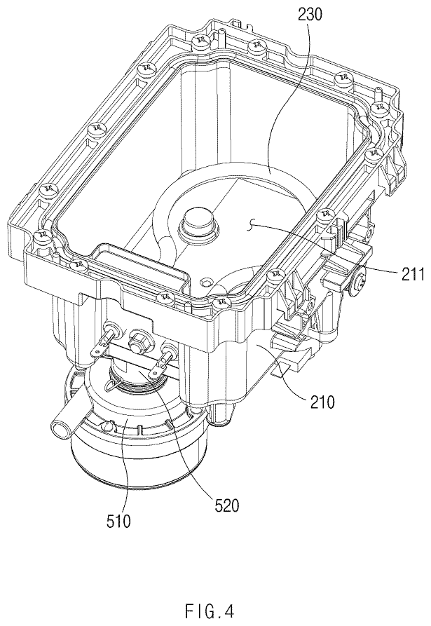

FIG. 1 is a view illustrating a body part of a water circulation mat according to an embodiment of the present disclosure. FIG. 2 is a view schematically illustrating a body part and a mat part of a water circulation mat according to an embodiment of the present disclosure. FIG. 3 is a view illustrating a tank part and a pump part of a water circulation mat according to an embodiment of the present disclosure. FIG. 4 is a view illustrating a tank part and a pump part of a water circulation mat according to an embodiment of the present disclosure.

Referring to FIGS. 1 to 4, a water circulation mat 1 according to an embodiment may include a body part 10, and a mat part 20 that is connected to the body part 10.

The body part 10 may supply water to the mat part 20, and water that circulates through the mat part 20 may be introduced back into the body part 10. Water that is returned from the mat part 20 to the body part 10 may undergo a cooling or heating process in an interior of the body part and then be supplied again to the mat part 20. The body part 10 is a device that processes water, and according to various embodiments, may be referred to as a water processing part.

The mat part 20 may be provided with an internal passage, in which water may flow, in an interior thereof. The internal passage may be surrounded by an outer cover that is formed of a fabric or a flexible material, and may be disposed in an interior of the outer cover in a serpentine form to uniformly supply cooling or heating to an entire area of the outer cover.

The mat part 20 may be configured such that water supplied from the body part 10 flows along the internal passage and is returned to the body part 10, and then is supplied again to the internal passage via a processing process (that is, cooling or heating) in the body part 10. That is, the internal passage may be connected to a passage provided in an interior of the body part 10, and as they are connected to each other, a water circulation loop having a closed loop form may be formed.

The body part 10 may include components that cool or heat water returned from the mat part 20, and supply the processed water to the mat part 20.

The body part 10 may include a case 100, a tank part 200, a cooling part 300, a heat dissipation part 400, a pump part 500, a plurality of valves 600, and a plurality of passages 700. However, the body part 10 may further include other components for operation of the water circulation mat 1, in addition to the components described above.

Hereinafter, components included in the body part 10 will be described first.

### Case 100

The case 100 is a component that defines an exterior of the body part 10, and may be provided in a shape, in which other components may be accommodated in an interior thereof. The case 100 may have a hexahedral shape having a specific length in an upward/downward direction D2, a forward/rearward direction D1, and a leftward/rightward direction (e.g., a direction perpendicular to the upward/downward direction D2 and the forward/rearward direction D1), but the present disclosure is not limited thereto.

The tank part 200, the cooling part 300, the heat dissipation part 400, the pump part 500, the plurality of valves 600, and the plurality of passages 700 may be accommodated in an interior of the case 100.

A plurality of vent holes 110 may be provided on an outer surface of the case 100 in the forward direction D11 such that inside air may be discharged to the outside. The vent holes 110 may be formed in a shape, a cross-section of which becomes larger as it goes in the forward direction D11 such that exhaust may be easily performed.

A water inlet port 120, through which water may be injected to the tank part 200, may be provided on sides of the case 100, except for a side thereof in an upward direction D21. The water inlet port 120 may be opened and closed by a cap.

A partition wall 130 that divides a space in an interior of the case 100 in the upward direction D21 in a forward/rearward direction D1 may be disposed in the interior of the case 100, and a printed board assembly (PBA) module 140 may be installed on one surface of the partition wall 130 on a forward direction D11 side.

The partition wall 130 may include an insulating material for insulating heat transfer between a space on the forward direction D11 side and a space on the rearward direction D12 side, which are divided by the partition wall 130. For example, specific heat may be generated in the space in the forward direction D11 and a temperature thereof may be high due to an operation of the PBA module 140 or an operation of the heat dissipation part 400, and the partition wall 130 may be formed of an insulating material or include an insulating material, so that heat in the space in the forward direction D11 may be prevented or minimized from being transferred to the tank part 200 disposed in the space in the rearward direction D12.

An interior of the case 100 may include a first space 160, in which the tank part 200 is disposed, a second space 170 that is located in the forward direction D11 of the first space 160 and is partitioned from the first space 160 by the partition wall 130, and a third space 180 that is located in the downward direction D22 of the first space 160 and the second space 170, and in which the cooling part 300, the heat dissipation fin 420, and a heat pipe 410 are disposed. The fans 430 and 440 and the PBA module 140 may be disposed in an interior of the second space 170. In an interior of the third space 180, the heat dissipation fin 420 and the heat pipe 410 may be disposed on the front side D11 of the third space 180 to be located on the lower side D22 of the fans 430 and 440, and the cooling part 300 may be disposed on the rear side D12 of the third space 180 to be located on a lower side of the tank part 200.

A connection pipe 150, to which a connector of the mat part 20 is connected, may be provided on an outer surface of the case 100 in the forward direction D11. The connection pipe 150 may include a water outlet pipe 151 for discharging water of the body part 10 to the mat part 20, and a first recovery pipe 152 and a second recovery pipe 153 for returning water of the mat part 20 to the body part 10.

For example, in the water circulation mat 1 according to the present disclosure, a first internal passage and a second internal passage that are separated from each other may be provided in an interior of the mat part 20, and when a connector and the connection pipe 150 are coupled to each other, the first recovery pipe 152 may be connected to the first internal passage, the second recovery pipe 153 may be connected to the second internal passage, and the water outlet pipe 151 may be connected to the first internal passage and the second internal passage (e.g., connected through a Y-shaped branch connector).

### Tank Part 200

Water may be stored in an interior of the tank part 200. The tank part 200 may be supplied with water from the outside through the water inlet port 120, and also, water returned from the mat part 20 may be stored. That is, the tank part 200 may be connected to at least a portion of return passages 720 and 730, through which water returned from the mat part 20 flows, and may be configured such that the returned water is supplied to the mat part 20 via the tank part 200.

The tank part 200 may include a base 210, in which a storage space 211 for storing water is formed, a cover 220 that covers the base 210, a heater 230 that is disposed in an interior of the base 210 to heat water stored in the storage space 211, and a tank temperature sensor 240 that is disposed in the interior of the base 210 to measure a temperature of the water stored in the storage space 211.

The tank part 200 may be connected to the pump part 500. For example, the tank part 200 may be connected to the pump part 500 such that water in an interior of the storage space 211 is supplied to it. The tank part 200 may be connected to at least a portion of return passages 720 and 730 such that the returned water may be stored. For example, the tank part 200 and the return passages 720 and 730 may be connected to each other by means of a first heating valve 620, and flow of water in the return passages 720 and 730 to the tank part 200 may be controlled in response to opening and closing of the first heating valve 620.

### Cooling Part 300

The cooling part 300 may be configured to cool water to be discharged to the mat part 20. The cooling part 300 may cool water delivered from the pump part 500 to a specific temperature and supply it to the mat part 20.

The cooling part 300 may be configured as a device that uses a Peltier element, in which temperature gradients are formed at opposite ends thereof when electric power is supplied.

For example, the cooling part 300 may include a first Peltier element 310, a second Peltier element 320, a first water jacket 330 that is disposed on an upper surface of the first Peltier element 310, a second water jacket 340 that is disposed on a lower surface of the second Peltier element 320, a support member 350 that is disposed between the lower surface of the first Peltier element 310 and the upper surface of the second Peltier element 320, and a connection pipe 360 that connects the first water jacket 330 and the second water jacket 340 such that they communicate with each other.

In each of the first Peltier element 310 and the second Peltier element 320, one of opposite surfaces thereof may be cooled and the remaining one may be heated. Water may be delivered close to low-temperature surfaces of the first Peltier element 310 and the second Peltier element 320 so that the water is cooled.

The first water jacket 330 and the second water jacket 340 are components that allow water to flow thereinto so that the water is cooled, and the water may flow from the first water jacket 330 to the second water jacket 340 through the connection pipe 360. The first water jacket 330 and the second water jacket 340 may contact low-temperature surfaces of the first Peltier element 310 and the second Peltier element 320 to cool water in interiors thereof.

The support member 350 may contact high-temperature surfaces of the first Peltier element 310 and the second Peltier element 320. The support member 350 is connected to the heat dissipation part 400 to dissipate heat of a high-temperature surface to the heat dissipation part 400. That is, as the support member 350 is connected to the heat dissipation part 400, the high-temperature surfaces of the first Peltier element 310 and the second Peltier element 320 may be cooled.

The cooling part 300 may be operated to form temperature gradients, in which the upper surface of the first Peltier element 310 and the lower surface of the second Peltier element 320 are of relatively low temperatures, and the lower surface of the first Peltier element 310 and the upper surface of the second Peltier element 320 are of relatively high temperatures, so that water delivered into interiors of the first water jacket 330 and the second water jacket 340 may be cooled.

### Heat Dissipation Part 400

The heat dissipation part 400 is a component for dissipating heat of the cooling part 300 and the PBA module 140, and may be configured to cool the cooling part 300 and the PBA module 140 by using flows of air.

The heat dissipation part 400 may include a heat pipe 410 that is connected to the support member 350 of the cooling part 300 such that heat may be transferred therebetween, a plurality of heat dissipation fins 420 through which the heat pipe 410 passes, a first fan 430 that is disposed at an upper portion of the heat dissipation fins 420 to form a flow of air in the upward direction D21, and a second fan 440 that is disposed to face the plurality of vent holes 110 to form a flow of air in the forward direction D11. The heat pipe 410 and the plurality of heat dissipation fins 420 may be referred to as a heat dissipation module for dissipating heat.

The heat pipe 410 may receive heat from the high-temperature surfaces of the Peltier elements 310 and 320 while contacting the support member 350. The plurality of heat dissipation fins 420 may be arranged along the forward/rearward direction D1 while being perpendicular to the heat pipe 410, so that a heat transfer area may be increased. The first fan 430 and the second fan 440 may be disposed perpendicular to each other. For example, a plurality of blades of the first fan 430 may be rotated around an axis that is parallel to the upward/downward direction D2, and a plurality of blades of the second fan 440 may be rotated around an axis that is parallel to the forward/rearward direction D1.

In response to an operation of the first fan 430, the air introduced into an interior of the case 100 may cool the plurality of heat dissipation fins 420 and the heat pipe 410 while passing through spaces between the plurality of heat dissipation fins 420 in the upward direction D21, and heat of the high-temperature surfaces of the Peltier elements 310 and 320 may be dissipated. The air that has passed through the plurality of heat dissipation fins 420 may be exhausted to a front side through the plurality of vent holes 110 by an operation of the second fan 440, and in this process, the PBA module 140 may be cooled. By the operation of the second fan 440, the air that has passed through the plurality of heat dissipation fins 420 may not flow downward again.

For example, the air introduced by the first fan 430 primarily cools the plurality of heat dissipation fins 420 and the heat pipe 410 and secondarily cools the PBA module 140 that is located on an upper side of them, and then is discharged to the outside by the second fan 440. It may be understood that a design in which the PBA module 140 is disposed on an upper side of the heat dissipation part 400 is applied to implement the cooling.

The above cooling method considers that a temperature of air that has absorbed heat of the plurality of heat dissipation fins 420 and the heat pipe 410 is lower than a temperature of the PBA module 140, and the air that has cooled the plurality of heat dissipation fins 420 and the heat pipe 410 may be reused for cooling of the PBA module 140 so that a cooling efficiency may be improved. For example, a temperature of air that has passed through the plurality of heat dissipation fins 420 may be about 40° C., and a temperature of the PBA module 140 may be about 80° C. to 100° C. However, the above-described numerical values are merely exemplary and are not limited thereto.

Meanwhile, although not illustrated, an air inlet port (not illustrated) may be formed in a partial area of an outer surface of the case 100, which faces the plurality of heat dissipation fins 420 in the leftward/rightward direction, such that external air may be introduced into an interior of the case 100 by an operation of the first fan 430. Furthermore, a filter (not illustrated) may be disposed between the plurality of heat dissipation fins 420 and the air inlet port.

### Pump Part 500

The pump part 500 may be a device that pumps water to allow the water to flow along a passage. A flow rate of water that flows due to the pump part 500 may be controlled. The pump part 500 may be connected to the tank part 200, the cooling part 300, a water outlet passage 710, and the return passages 720 and 730.

The pump part 500 may pump water returned from the mat part 20 toward the water outlet passage 710. The pump part 500 may receive water that has been returned from the mat part 20 and has passed through a first cooling valve 610, or water that has been returned from the mat part 20 and has passed through the first heating valve 620 and the tank part 200. To cool the water that has passed through the first cooling valve 610, the water may be pumped to the cooling part 300 by the pump part 500, and the water that has passed through the first heating valve 620 and the tank part 200 to be heated may be pumped toward the second heating valve 640 by the pump part 500.

The pump part 500 may include a pump body 510 that drives pumping of water, and a branch connection pipe 520 that connects the pump body 510 to the tank part 200 and the first cooling valve 610. The branch connection pipe 520 may include a first connection pipe 521 that is connected to the base 210 to communicate with the storage space 211 of the tank part 200, and a second connection pipe 522 that is connected to the first cooling valve 610. For example, water in an interior of the tank part 200 may be delivered to the pump body 510 through the first connection pipe 521, and water that has passed through the first cooling valve 610 may be delivered to the pump body 510 through the second connection pipe 522.

The water delivered to the pump part 500 through the first connection pipe 521 may be water that is returned from the mat part 20, passes through the first heating valve 620, and is heated in the tank part 200, or may be water that is stored in the tank part 200 regardless of return. For example, when water circulating through the mat part 20 is insufficient, water in the tank part 200 may be automatically delivered to the pump part 500 through the first connection pipe 521, and this may be irrelevant to cooling and heating of returned water.

### Plurality of Valves 600

A plurality of valves 600 may be components for selectively adjusting a passage through which water flows. That is, a passage through which water flows may be determined depending on opening and closing of the plurality of valves 600.

The plurality of valves 600 may include a first cooling valve 610, a first heating valve 620, a second cooling valve 630, a second heating valve 640, a first return valve 650, and a second return valve 660.

Here, the terms “cooling valve” and “heating valve” distinguish between valves that are opened during operation in a cooling mode and valves that are opened during operation in a heating mode in the water circulation mat 1 of the present disclosure, and they do not mean that cooling or heating is performed by the valves themselves.

The first cooling valve 610 may be provided at an inlet end of the pump part 500 to adjust introduction of returned water to the pump part 500. The first heating valve 620 may be connected to the tank part 200 to adjust introduction of returned water to the tank part 200.

The second cooling valve 630 may be provided at an outlet end of the cooling part 300 to adjust introduction of water that has passed through the cooling part 300 into the water outlet passage 710. The second heating valve 640 may be provided at an outlet end of the pump part 500 to adjust introduction of water that has been directly pumped from the pump part 500 while not passing via the cooling part 300 into the water outlet passage 710.

The first return valve 650 may be provided at a branch point of a first return passage 720 to adjust returned water flowing through the first return passage 720 to flow to any one of a first branch return passage 721 or a second branch return passage 722. The first branch return passage 721 may be connected to the first cooling valve 610, and the second branch return passage 722 may be connected to the first heating valve 620.

The second return valve 660 may be provided at a branch point of a second return passage 730 to adjust flows of water returned through the second return passage 730 to any one of a third branch return passage 731 and a fourth branch return passage 732. The third branch return passage 731 may be connected to the first cooling valve 610, and the fourth branch return passage 732 may be connected to the first heating valve 620.

The first return valve 650 and the second return valve 660 may block the water in interiors of the first return passage 720 and the second return passage 730 from flowing to the respective branch passages. That is, the first return valve 650 may block the water from flowing to either the first branch return passage 721 or the second branch return passage 722 from the first return passage 720. The same applies to the second return valve 660.

The water circulation mat 1 may be provided with two internal passages that are separated from each other in an interior of the mat part 20, and water may be circulated in only one of the two internal passages, which corresponds to the opened return valve, by closing any one of the first return valve 650 and the second return valve 660. Accordingly, the temperature of water that flows through the two internal passages may be individually adjusted.

Although not illustrated, the internal passage may include a first internal passage (or a left internal passage) that is connected to the first return passage 720, and a second internal passage (or a right internal passage) that is connected to the second return passage 730. For example, when flows of water to the first branch return passage 721 and the second branch return passage 722 are blocked by closing the first return valve 650, and a flow to any one of the third branch return passage 731 or the fourth branch return passage 732 is allowed by opening the second return valve 660, circulation of water between the first internal passage connected to the first return passage 720 and the body part 10 is temporarily stopped because water in an interior of the first internal passage is not returned, and water in an interior of the internal passage of the mat part 20 connected to the second return passage 730 is returned, so that the returned water is circulated while being supplied again after being processed in the body part 10. Through this, temperatures of left and right portions of the mat part 20 may be individually adjusted.

### Plurality of Passages 700

The plurality of passages 700 may connect the mat part 20 (particularly, an internal passage of the mat part 20) to at least one of the tank part 200, the cooling part 300, and the pump part 500 such that water returned from the mat part 20 may be supplied to the mat part 20 again after being cooled or heated in the body part 10.

The plurality of passages 700 may include a water outlet passage 710, a first return passage 720, a second return passage 730, a cooling passage 740, and a heating passage 750.

The water outlet passage 710 may connect the second cooling valve 630 and the second heating valve 640 to the mat part 20. The water outlet passage 710 may be branched from one point and may be configured such that a first branch water outlet passage 711 is connected to the second cooling valve 630 and a second branch water outlet passage 712 is connected to the second heating valve 640. That is, the water that has passed through the second cooling valve 630 flows to the first water outlet passage 710 through the first branch water outlet passage 711, and the water that has passed through the second heating valve 640 flows to the first water outlet passage 710 through the second branch water outlet passage 712.

The water outlet passage 710 may be connected to the water outlet pipe 151 provided in the case 100. That is, the water outlet passage 710 may be connected to the internal passage of the mat part 20 through the water outlet pipe 151. The water outlet passage 710 may be provided with an outlet temperature sensor 810 for measuring a temperature of the water that is discharged toward the mat part 20. The outlet temperature sensor 810 may be provided between the internal passage of the mat part 20 (or the water outlet pipe 151) and a branch point of the water outlet passage 710.

The first return passage 720 may connect the first internal passage of the mat part 20 to the first cooling valve 610 and the first heating valve 620. A first return valve 650 may be provided on the first return passage 720. The first return passage 720 may be branched with respect to the first return valve 650, and may be configured such that a first branch return passage 721 is connected to the first cooling valve 610 and a second branch return passage 722 is connected to the first heating valve 620. That is, the water returned from the first internal passage through the first return passage 720 may be discharged to the first internal passage again after flowing to the first branch return passage 721 and being cooled by the cooling part 300 when cooling is necessary, and may be discharged to the first internal passage again after flowing to the second branch return passage 722 and being heated by the heater 230 when heating is necessary.

The first return passage 720 may be connected to the first recovery pipe 152 provided in the case 100. That is, the first return passage 720 may be connected to the first internal passage of the mat part 20 through the first recovery pipe 152. The first return passage 720 may be provided with a first return temperature sensor 820 for measuring a temperature of the water returned from the first internal passage. The first return temperature sensor 820 may be provided between the first internal passage of the mat part 20 (or the first recovery pipe 152) and the first return valve 650.

The second return passage 730 may connect the second internal passage of the mat part 20 to the first cooling valve 610 and the first heating valve 620. A second return valve 660 may be provided on the second return passage 730. The second return passage 730 may be branched with respect to the second return valve 660, and may be configured such that a third branch return passage 731 is connected to the first cooling valve 610 and a fourth branch return passage 732 is connected to the first heating valve 620. That is, the water returned from the second internal passage through the second return passage 730 may be discharged to the second internal passage again after flowing to the third branch return passage 731 and being cooled by the cooling part 300 when cooling is necessary, and may be discharged to the second internal passage again after flowing to the fourth branch return passage 732 and being heated by the heater 230 when heating is necessary.

The second return passage 730 may be connected to the second recovery pipe 153 provided in the case 100. That is, the second return passage 730 may be connected to the second internal passage of the mat part 20 through the second recovery pipe 153. The second return passage 730 may be provided with a second return temperature sensor 830 for measuring a temperature of the water returned from the second internal passage. The second return temperature sensor 830 may be provided between the second internal passage of the mat part 20 (or the second recovery pipe 153) and the second return valve 660.

The cooling passage 740 may connect the pump part 500 to the second cooling valve 630, and may extend across the cooling part 300. That is, opposite ends of the cooling passage 740 may be connected to the pump part 500 and the second cooling valve 630, and the cooling part 300 may be provided between the pump part 500 and the second cooling valve 630. Accordingly, after the water pumped by the pump part 500 is cooled in the cooling part 300, it may flow toward the second cooling valve 630, and when the second cooling valve 630 is opened, the cooled water may be discharged to the mat part 20 through the water outlet passage 710.

The heating passage 750 may be branched from the cooling passage 740 and may connect the pump part 500 to the second heating valve 640. That is, the heating passage 750 may be connected to the second heating valve 640 while communicating with the cooling passage 740 connected to the pump part 500. Accordingly, after being heated in the tank part 200, the water delivered to the pump part 500 may be pumped by the pump part 500 and flow toward the second heating valve 640, and when the second heating valve 640 is opened, the heated water may be discharged to the mat part 20 through the water outlet passage 710.

Meanwhile, because the heating passage 750 is branched from the cooling passage 740, the water pumped by the pump part 500 may flow along both the heating passage 750 and the cooling passage 740, and discharge of the water through the water outlet passage 710 is adjusted by opening and closing the second cooling valve 630 and the second heating valve 640. That is, when the returned water is cooled and discharged, the water delivered to the pump part 500 through the first cooling valve 610 may flow to both the cooling passage 740 and the heating passage 750 when being pumped by the pump part 500, but because the second heating valve 640 is maintained in a closed state, only the water that has passed through the cooling part 300 may be discharged.

The plurality of passages 700 may further include a first connection passage 770 that connects the tank part 200 to the pump part 500, and a second connection passage 780 that connects the first connection passage 770 to the first cooling valve 610. The water in the interior of the tank part 200 may flow to the pump part 500 through a first connection passage 770. The water that has passed through the first cooling valve 610 may be introduced into the first connection passage 770 through the second connection passage 780, and then, may flow to the pump part 500. As illustrated in FIG. 3, the first connection passage 770 may be formed by the first connection pipe 521, and the second connection passage 780 may be formed by the second connection pipe 522.

The plurality of passages 700 may further include a third connection passage 760 that connects the second branch return passage 722 and the fourth branch return passage 732 to the first heating valve 620. For example, the third connection passage 760 may be provided between a point, at which the second branch return passage 722 and the fourth branch return passage 732 are connected to each other, and the first heating valve 620. That is, opposite ends of the third connection passage 760 may be connected to a junction point of the second branch return passage 722 and the fourth branch return passage 732 and to the first heating valve 620, respectively. Accordingly, the water that flows along the second branch return passage 722 and the fourth branch return passage 732, respectively, may be delivered to the first heating valve 620 after merging in the third connection passage 760.

The water circulation mat 1 according to an embodiment may further include a processor (not illustrated) that controls components of the water circulation mat 1. The processor may be provided in an interior of the body part 10, but is not limited thereto.

The processor may control the heater 230, the cooling part 300, the fans 430 and 440, the pump part 500, and the plurality of valves 600. That is, the processor may generate and provide control signals for operations of the heater 230, the cooling part 300, the fans 430 and 440, the pump part 500, and the plurality of valves 600. Furthermore, the processor may receive temperature information from the plurality of temperature sensors 240, 810, 820, and 830. The processor may control the water circulation mat 1 based on a difference between a temperature measured by the return temperature sensors 820 and 830 and a preset temperature.

The processor is a component capable of performing logical operations for executing control commands, and may include a central processing unit (CPU). The processor may be connected to various components of the water circulation mat 1 according to an embodiment of the present disclosure to transmit signals according to control commands to the components, and may be connected to various sensors or acquisition units to receive acquired information in a form of signals. The processor may be electrically connected to the respective components, and thus may be connected by wires or may communicate with the components through a communication module capable of wireless communication.

Furthermore, the water circulation mat 1 may further include a storage medium (not illustrated), and control commands executed by the processor are stored and used. The storage medium may be a device, such as a hard disk drive (HDD), a solid state drive (SSD), a server, a volatile medium, or a non-volatile medium, but a type thereof is not limited thereto. In addition, data required for the processor to perform operations may be further stored in the storage medium.

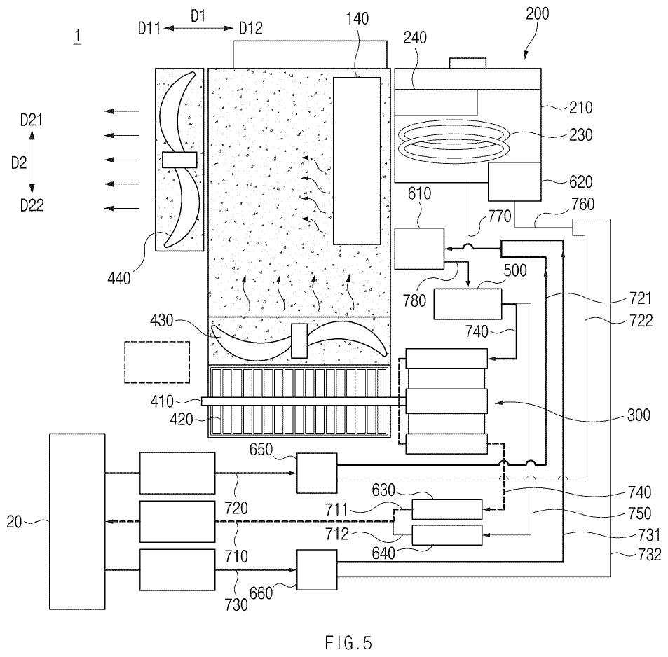

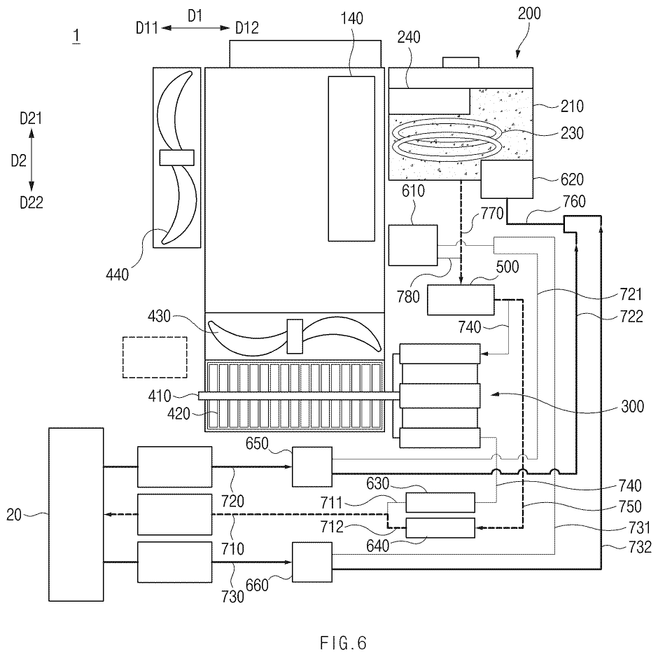

Hereinafter, operations of a cooling mode and a heating mode and circulation paths of water during the operations in the water circulation mat 1 will be described with reference to FIGS. 5 and 6.

FIG. 5 is a view illustrating an operation of a cooling mode in a water circulation mat according to an embodiment of the present disclosure. FIG. 6 is a view illustrating an operation of a heating mode in a water circulation mat according to an embodiment of the present disclosure.

FIG. 5 is a view for describing a case in which a cooling mode is operated in the water circulation mat 1 described with reference to FIGS. 1 to 4, and FIG. 6 is a view for describing a case in which a heating mode is operated in the water circulation mat 1 described with reference to FIGS. 1 to 4, and hereinafter, repeated descriptions thereof will be omitted.

Hereinafter, a description will be made based on water returned from the first internal passage, but this is merely for convenience of explanation, and the following description may be equally applied to water returned from the second internal passage.

### Cooling Mode

First, referring to FIG. 5, the water circulation mat 1 may be operated in a cooling mode (or a cooling system) when a temperature of the mat part 20 is to be lowered. In FIG. 5, a path through which water circulates is indicated by a thick line, a path of water before being cooled after being returned is indicated by a thick solid line, and a path of cooled water is indicated by a thick dotted line.

When a temperature of the first internal passage is to be lowered, the water returned through the first return passage 720 may be delivered to the first branch return passage 721 via the first return valve 650. That is, the first return valve 650 is operated such that the water in an interior of the first return passage 720 flows to the first branch return passage 721 connected to the first cooling valve 610.

The water introduced into the first branch return passage 721 is delivered to the pump part 500 via the first cooling valve 610 as the first cooling valve 610 is opened, and, at this time, the first heating valve 620 is in a closed state. The water delivered to the pump part 500 may be pumped by the pump part 500 and delivered to the cooling part 300, and may be delivered to the second cooling valve 630 after being cooled to a specific temperature in the cooling part 300. The water pumped from the pump part 500 is delivered to the second cooling valve 630 via the cooling part 300 while flowing through the cooling passage 740.

The water delivered to the second cooling valve 630 may flow through the first branch water outlet passage 711 and the water outlet passage 710 as the second cooling valve 630 is opened, and may be discharged to the mat part 20. In this case, because the second heating valve 640 is in a closed state, only the water that is cooled after passing through the cooling part 300 may be delivered to the water outlet passage 710. An outlet temperature sensor 810 provided in the water outlet passage 710 may measure a temperature of the discharged water. This is to prevent overcooling of the discharged water.

That is, when a temperature of the first internal passage is lowered, the water returned from the first internal passage is discharged to the mat part 20 after sequentially passing through the first return passage 720, the first return valve 650, the first branch return passage 721, the first cooling valve 610, the pump part 500, the cooling passage 740, the cooling part 300, the cooling passage 740, the second cooling valve 630, the first branch water outlet passage 711, and the water outlet passage 710.

Likewise, even when a temperature of the second internal passage is to be lowered, the water returned from the second internal passage is discharged to the mat part 20 after sequentially passing through the second return passage 730, the second return valve 660, the third branch return passage 731, the first cooling valve 610, the pump part 500, the cooling passage 740, the cooling part 300, the cooling passage 740, the second cooling valve 630, the first branch water outlet passage 711, and the water outlet passage 710.

When the cooling mode is operated, the cooling part 300 is operated, and thus, it is required to dissipate heat of the cooling part 300 is required, and to achieve this, the first fan 430 and the second fan 440 may be operated to cool the cooling part 300 and the PBA module 140.

### Heating Mode

Next, referring to FIG. 6, the water circulation mat 1 may be operated in a heating mode (or a heating system) when a temperature of the mat part 20 is to be increased. In FIG. 6, a path through which water circulates is indicated by a thick line, a path of water before being heated after being returned is indicated by a thick solid line, and a path of heated water is indicated by a thick dotted line.

When a temperature of the first internal passage is to be increased, the water returned through the first return passage 720 may be delivered to the second branch return passage 722 via the first return valve 650. That is, the first return valve 650 is operated such that the water in an interior of the first return passage 720 flows to the second branch return passage 722 connected to the first heating valve 620.

The water introduced into the second branch return passage 722 is delivered to the tank part 200 via the first heating valve 620 as the first heating valve 620 is opened, and, at this time, the first cooling valve 610 is in a closed state. The water delivered to the tank part 200 is heated to a specific temperature by the heater 230 in an interior of the tank part 200, and is then delivered to the pump part 500. The water delivered to the pump part 500 may be pumped by the pump part 500, and may be delivered to the second heating valve 640 through the heating passage 750.

The water delivered to the second heating valve 640 may flow through the second branch water outlet passage 712 and the water outlet passage 710 as the second heating valve 640 is opened, and may be discharged to the mat part 20. In this case, because the second cooling valve 630 is in a closed state, only the water that has been directly pumped from the pump part 500 while not passing through the cooling part 300 after being heated may be delivered to the water outlet passage 710. An outlet temperature sensor 810 provided in the water outlet passage 710 may measure a temperature of the discharged water. This is to prevent overheating of the discharged water.

That is, when a temperature of the first internal passage is to be increased, the water returned from the first internal passage is discharged to the mat part 20 after sequentially passing through the first return passage 720, the first return valve 650, the second branch return passage 722, the first heating valve 620, the tank part 200 (that is, the heater 230), the pump part 500, the heating passage 750, the second heating valve 640, the second branch water outlet passage 712, and the water outlet passage 710.

Likewise, even when a temperature of the second internal passage is to be increased, the water returned from the second internal passage is discharged again to the mat part 20 after sequentially passing through the second return passage 730, the second return valve 660, the fourth branch return passage 732, the first heating valve 620, the tank part 200 (that is, the heater 230), the pump part 500, the heating passage 750, the second heating valve 640, the second branch water outlet passage 712, and the water outlet passage 710.

Meanwhile, an operation of adjusting a temperature of the first internal passage and an operation of adjusting a temperature of the second internal passage may be performed simultaneously or may be performed sequentially. For example, when only a temperature of the first internal passage is adjusted, the water in the first internal passage may be circulated in a state, in which the water in the second internal passage does not circulate, by completely closing the second return valve 660.

Furthermore, the water circulation mat 1 according to the present disclosure may be operated such that the first internal passage is cooled and the second internal passage is heated. In this case, the water in the first internal passage and the second internal passage is not circulated at the same time, and may be circulated sequentially. An operation may be performed in a scheme of, when a temperature of the first internal passage is lowered and a temperature of the second internal passage is increased, supplying the cooled water to the first internal passage while being operated in the cooling mode in a state, in which the second return valve 660 is fully closed, and thereafter, supplying the heated water to the second internal passage while being operated in the heating mode in a state, in which the first return valve 650 is fully closed. In this case, an operation of supplying cooled water and an operation of supplying heated water may be alternately performed once until a temperature of the water reaches a preset temperature.

According to an embodiment of the present disclosure, heat dissipation efficiency may be improved by performing heat dissipation for the cooling part and the PBA module through a single heat dissipation part, and user convenience may be improved by separately controlling temperatures on left and right sides.

The above description is merely an example of the technical idea of the present disclosure, and various modifications and variations may be made by one skilled in the art without departing from the essential characteristic of the present disclosure. Accordingly, embodiments of the present disclosure are intended not to limit but to explain the technical idea of the present disclosure, and the scope and spirit of the present disclosure is not limited by the above embodiments. The scope of protection of the present disclosure should be construed by the attached claims, and all equivalents thereof should be construed as being included within the scope of the present disclosure.

What is claimed is:

1. A water circulation mat comprising:
a mat part including an internal passage configured such that water flows in an interior thereof; and
a body part connected to the internal passage, and configured to supply water to the internal passage or receive water returned from the internal passage,
wherein the body part includes:
a case including an accommodation space in an interior thereof;
a cooling part disposed at a lower portion of the accommodation space;
a heat dissipation module, at least a portion of which is connected to the cooling part, and disposed on a front side of the cooling part in the accommodation space;
a first fan disposed at an upper portion of the heat dissipation module in the accommodation space, and configured to form a flow of air passing through the heat dissipation module in an upward direction; and
a second fan disposed perpendicularly to the first fan, and configured to form a flow of air such that air passing through the heat dissipation module is discharged in a forward direction of the case.

2. The water circulation mat of claim 1, wherein a PBA module is disposed in a space of the accommodation space located at an upper portion of the first fan, and
wherein the flow of air formed by the first fan passes through the heat dissipation module to cool the cooling part, and then flows to the space, in which the PBA module is disposed, to cool the PBA module.

3. The water circulation mat of claim 2, wherein the heat dissipation module includes:
a heat pipe connected to the cooling part to be thermally transferable; and
a plurality of heat dissipation fins, through which the heat pipe passes.

4. The water circulation mat of claim 1, wherein the cooling part includes:
a Peltier element configured to cool water to be supplied to the internal passage.

5. The water circulation mat of claim 2, further comprising:
a tank part including a storage space, in which water is stored in an interior thereof, including a heater disposed in the interior of the storage space.

6. The water circulation mat of claim 5, wherein the tank part is disposed on a rear side of the space, in which the PBA module is disposed, and
wherein a partition wall including an insulating material is disposed between the tank part and the PBA module.

7. The water circulation mat of claim 5, wherein the internal passage includes a first internal passage and a second internal passage separated from each other,
wherein the body part includes a first return passage connected to the first internal passage and a second return passage connected to the second internal passage, and
wherein when an operation mode for supplying cooled water to the internal passage is defined as a cooling mode, and an operation mode for supplying heated water to the internal passage is defined as a heating mode,
each of the first return passage and the second return passage includes two branch passages, and water flows through one branch passage in the cooling mode and water flows through the remaining branch passage in the heating mode.

8. The water circulation mat of claim 7, wherein the first return passage includes:
a first branch return passage configured such that returned water flows to the cooling part; and
a second branch return passage configured such that returned water flows to the tank part, and
wherein the second return passage includes:
a third branch return passage configured such that returned water flows to the cooling part; and
a fourth branch return passage configured such that returned water flows to the tank part.

9. The water circulation mat of claim 8, wherein the body part further includes:
a pump part configured to pump water; and
a first cooling valve provided at an inlet end of the pump part, and to which the first branch return passage and the second branch return passage are connected, and
wherein the first cooling valve is configured to control a flow of water between the return passage and the pump part.

10. The water circulation mat of claim 9, wherein the body part further includes:
a first heating valve connected to the tank part, and to which the second branch return passage and the fourth branch return passage are connected, and
wherein the first heating valve is configured to control a flow of water between the return passage and the tank part.

11. The water circulation mat of claim 10, wherein the body part further includes:
a water outlet passage connected to the internal passage;
a second cooling valve configured to control a flow of water cooled in the cooling part to the water outlet passage;
and a second heating valve configured to control a flow of water heated in the tank part to the water outlet passage.

12. The water circulation mat of claim 11, wherein the body part further includes:
a first return valve provided at a branch point of the first return passage, and
wherein the first return valve performs a control to block returned water from flowing to the first branch return passage and the second branch return passage, or to cause the returned water to flow to any one of the first branch return passage and the second branch return passage.

13. The water circulation mat of claim 12, wherein the body part further includes:
a second return valve provided at a branch point of the second return passage, and
wherein the second return valve performs a control to block returned water from flowing to the third branch return passage and the fourth branch return passage, or to cause the returned water to flow to any one of the third branch return passage and the fourth branch return passage.

14. The water circulation mat of claim 13, wherein in the cooling mode,
the first cooling valve and the second cooling valve are opened,
the first heating valve and the second heating valve are closed, and
the first return valve and the second return valve cause returned water to flow to the first branch return passage and the third branch return passage, respectively.

15. The water circulation mat of claim 14, wherein water introduced into the first branch return passage and the third branch return passage is cooled to a specific temperature after sequentially passing through the first cooling valve, the pump part, the cooling part, the second cooling valve, and the water outlet passage, and then is discharged to the first internal passage or the second internal passage.

16. The water circulation mat of claim 13, wherein in the heating mode,
the first heating valve and the second heating valve are opened,
the first cooling valve and the second cooling valve are closed, and
the first return valve and the second return valve cause returned water to flow to the second branch return passage and the fourth branch return passage, respectively.

17. The water circulation mat of claim 16 wherein water introduced into the second branch return passage and the fourth branch return passage is heated to a specific temperature after sequentially passing through the first heating valve, the tank part, the pump part, the second heating valve, and the water outlet passage, and then is discharged to the first internal passage or the second internal passage.

18. The water circulation mat of claim 7, wherein the body part further includes:
a processor configured to control an operation of the body part;
a first return temperature sensor provided in the first return passage; and
a second return temperature sensor provided in the second return passage, and
wherein the processor is configured to:
control operations of the cooling mode and the heating mode based on temperature information measured by the first return temperature sensor and the second return temperature sensor.
